(19) United States
(12) Patent Application Publication
(10) Pub. No.: US 2026/0231659 A1
(43) Pub. Date: Aug. 6, 2026

(54) DISPLAY PANEL AND DISPLAY DEVICE

(71) Applicant: HUBEI YANGTZE INDUSTRIAL INNOVATION CENTER OF ADVANCED DISPLAY CO., LTD., Wuhan (CN)

(72) Inventors: Dandan Zang, Wuhan (CN); Li Xiao, Wuhan (CN); Yu Cai, Wuhan (CN); Yong Yuan, Wuhan (CN)

(21) Appl. No.: 19/629,265

(22) Filed: Mar. 26, 2026

(30) Foreign Application Priority Data
Nov. 26, 2025 (CN) 202511759724.9

(51) Int. Cl. H10K 59/80; H10K 59/38; H10K 59/50; H10K 102/00

(52) U.S. Cl. CPC H10K 59/8792; H10K 59/38; H10K 59/50; H10K 59/879; H10K 2102/351

(57) ABSTRACT

A display panel includes display region, photosensitive region, array layer, light-emitting functional layer, first functional layer, and light-adjusting portion. The light-emitting functional layer is located on a side of array layer and electrically connected to array layer. The first functional layer is located on a side of the light-emitting functional layer away from the array layer, and includes light-shielding layer and light-filtering portion. The light-shielding layer includes display openings and photosensitive opening. Along a thickness direction of the display panel, display openings and the photosensitive opening penetrate through the light-shielding layer. The display openings are located in the display region, the photosensitive opening is located in photosensitive region, and the light-filtering portion is located in display openings. The light-adjusting portion is located in the photosensitive opening. Along the thickness direction of display panel, a thickness of light-adjusting portion is less than or equal to a thickness of light-filtering portion.

### CROSS-REFERENCE TO RELATED APPLICATION

The present application claims priority to Chinese Patent Application No. 202511759724.9, filed on Nov. 26, 2025, the content of which is incorporated herein by reference in its entirety.

### TECHNICAL FIELD

The present disclosure relates to the field of display technologies, and in particular, to a display panel and a display device.

### BACKGROUND

With the continuous development of science and technology, more and more display products, such as mobile phones, tablet computers, notebook computers and intelligent wearable devices, are widely applied in people's daily life and work, bringing great convenience to people's daily life and work, and becoming indispensable important tools for people today.

At present, some display panels, especially panels applied to terminals such as smart phones, generally integrate an ambient light sensor (LS) outside a pixel light-emitting region of the display panel to achieve a full-screen design, and sense light through a light-transmitting hole of the display screen (i.e., an LS photosensitive hole). Although such a design solution achieves concealment of the sensor, new problems of appearance and display uniformity are introduced.

### SUMMARY

An aspect of the present disclosure provides a display panel. The display panel includes a display region and a photosensitive region. The display region at least partially surrounds the photosensitive region. The display panel includes an array layer, a light-emitting functional layer, a first functional layer, and a light-adjusting portion. The light-emitting functional layer is located on a side of the array layer and electrically connected to the array layer. The first functional layer is located on a side of the light-emitting functional layer away from the array layer, the first functional layer includes a light-shielding layer and a light-filtering portion, the light-shielding layer includes a plurality of display openings and at least one photosensitive opening, and along a thickness direction of the display panel, the plurality of display openings and the at least one photosensitive opening penetrate through the light-shielding layer; and the display openings are located in the display region, the photosensitive opening is located in the photosensitive region, and the light-filtering portion is located in one of the display openings. The light-adjusting portion is located in the photosensitive opening, and along the thickness direction of the display panel, a thickness of the light-adjusting portion is less than or equal to a thickness of the light-filtering portion.

Another aspect of the present disclosure further provides a display device. The display device includes a display panel. The display panel includes a display region and a photosensitive region. The display region at least partially surrounds the photosensitive region. The display panel includes: an array layer, a light-emitting functional layer, a first functional layer, and a light-adjusting portion. The light-emitting functional layer is located on a side of the array layer and electrically connected to the array layer. The first functional layer is located on a side of the light-emitting functional layer away from the array layer, the first functional layer includes a light-shielding layer and a light-filtering portion, the light-shielding layer includes a plurality of display openings and at least one photosensitive opening, and along a thickness direction of the display panel, the plurality of display openings and the at least one photosensitive opening penetrate through the light-shielding layer; and the display openings are located in the display region, the photosensitive opening is located in the photosensitive region, and the light-filtering portion is located in one of the display openings. The light-adjusting portion is located in the photosensitive opening, and along the thickness direction of the display panel, a thickness of the light-adjusting portion is less than or equal to a thickness of the light-filtering portion.

### BRIEF DESCRIPTION OF DRAWINGS

The drawings herein are incorporated in and constitute a part of the description, which illustrate embodiments in accordance with the present disclosure and, together with the description, serve to explain the principles of the present disclosure.

In order to more clearly illustrate the technical solutions in the embodiments of the present disclosure or in the related art, the drawings, which are intended to be used in the description of the embodiments or the related art, are briefly described as below, and it will be apparent that other drawings may be obtained by those skilled in the art according to these drawings.

FIG. 1 is a planar structural diagram of a display panel according to some embodiments of the present disclosure;

FIG. 2 is a schematic diagram of a layer of a display panel provided with a photosensitive region in the related art;

FIG. 3 is a schematic diagram of a layer in a display region of the display panel shown in FIG. 1 according to some embodiments of the present disclosure;

FIG. 4 is a cross-sectional view along a direction BB of the display panel shown in FIG. 1 according to some embodiments of the present disclosure;

FIG. 5 is a planar schematic diagram of a display panel in a photosensitive region according to some embodiments of the present disclosure;

FIG. 6 is a planar schematic diagram of a display panel in a photosensitive region according to some embodiments of the present disclosure;

FIG. 7 is a planar schematic diagram of a display panel in a photosensitive region according to some embodiments of the present disclosure;

FIG. 8 is a planar schematic diagram of a display panel in a photosensitive region according to some embodiments of the present disclosure;

FIG. 9 is a cross-sectional view along a direction BB of the display panel shown in FIG. 1 according to some embodiments of the present disclosure;

FIG. 10 is a cross-sectional view along a direction BB of the display panel shown in FIG. 1 according to some embodiments of the present disclosure;

FIG. 11 is an enlarged schematic diagram of a light-adjusting portion shown in FIG. 10 according to some embodiments of the present disclosure;

FIG. 12 is a schematic diagram of a reflection spectrum of a photosensitive region according to some embodiments of the present disclosure;

FIG. 13 is a cross-sectional view along a direction BB of the display panel shown in FIG. 1 according to some embodiments of the present disclosure;

FIG. 14 is a cross-sectional view along a direction BB of the display panel shown in FIG. 1 according to some embodiments of the present disclosure;

FIG. 15 is a cross-sectional view along a direction BB of the display panel shown in FIG. 1 according to some embodiments of the present disclosure;

FIG. 16 is a planar schematic diagram of a display device according to some embodiments of the present disclosure; and

FIG. 17 is a cross-sectional view along a direction CC of the display device shown in FIG. 16 according to some embodiments of the present disclosure.

### DESCRIPTION OF EMBODIMENTS

In order to more clearly understand the above-mentioned purposes, features and advantages of the present disclosure, the solutions of the present disclosure will be further described below. It should be noted that the embodiments of the present disclosure and features in the embodiments may be combined with each other without conflict.

In the following description, many specific details are set forth to fully understand the present disclosure, but the present disclosure may be implemented in other manners different from those described herein. It is apparent that the embodiments in the specification are merely a part of the embodiments of the present disclosure, not all of the embodiments of the present disclosure.

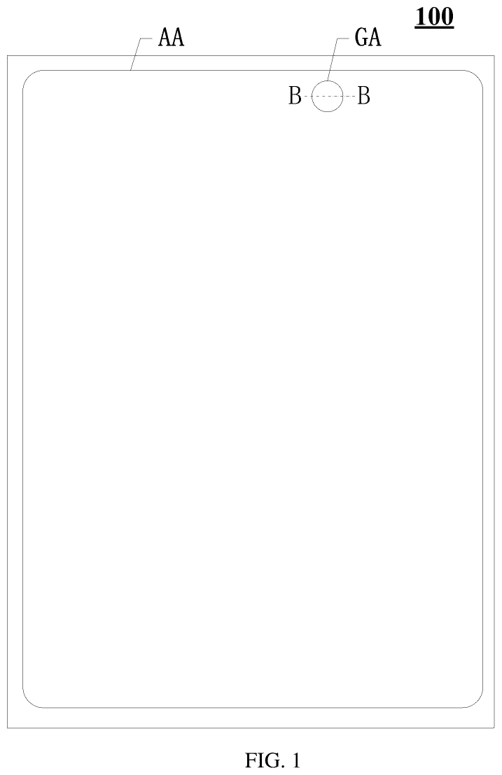

FIG. 1 is a planar structural diagram of a display panel according to some embodiments of the present disclosure. The display panel 100 according to the embodiments of the present disclosure includes a display region AA and a photosensitive region GA, and the display region AA at least partially surrounds the photosensitive region GA. The photosensitive region GA is an important region in which a photosensitive device (for example, an ambient light sensor) is integrated under the screen to realize a full-screen design. The main function of the photosensitive region GA is to serve as a light channel, allowing external ambient light to penetrate through the display panel and to reach the ambient light sensor located under the screen, for the ambient light sensor to receive and detect the intensity of the external ambient light, thereby realizing an ambient light detection function. According to the intensity of ambient light, the system can automatically adjust the display brightness of the screen to optimize the user's visual comfort and battery life. It should be noted that the planar structure of the display panel shown in FIG. 1 is merely illustrative and does not limit an actual shape of the display panel. The specific position of the photosensitive region GA in the display panel and the shape of the photosensitive region GA are merely illustrative, which is not limited in the present disclosure.

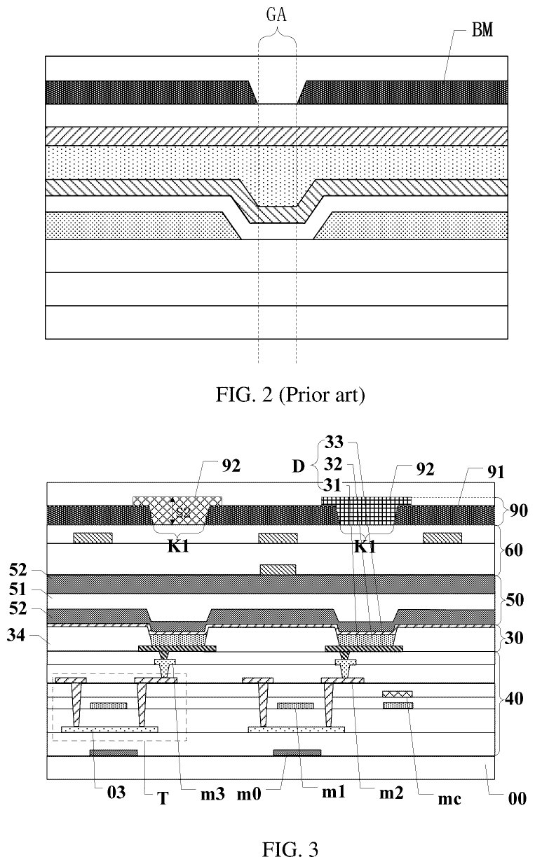

FIG. 2 is a schematic diagram of a layer of a display panel provided with a photosensitive region GA in the related art. In order to allow light to pass through, some of the layers in the photosensitive region GA of the display panel needs to be hollowed out. For example, the light-shielding layer BM is hollowed out. However, the hollowed out manner results in a large difference between the film stack structure of the region and that of the surrounding region, making the film stack structure of the region significantly different from that of the surrounding pixel light-emitting regions, and thus resulting in a sharp increase in the reflectivity of the photosensitive region GA. In the screen-off state, due to the increase in the reflectivity, the hollowed hole of the photosensitive region GA is very obvious, which seriously affects the product appearance and the user's experience effect.

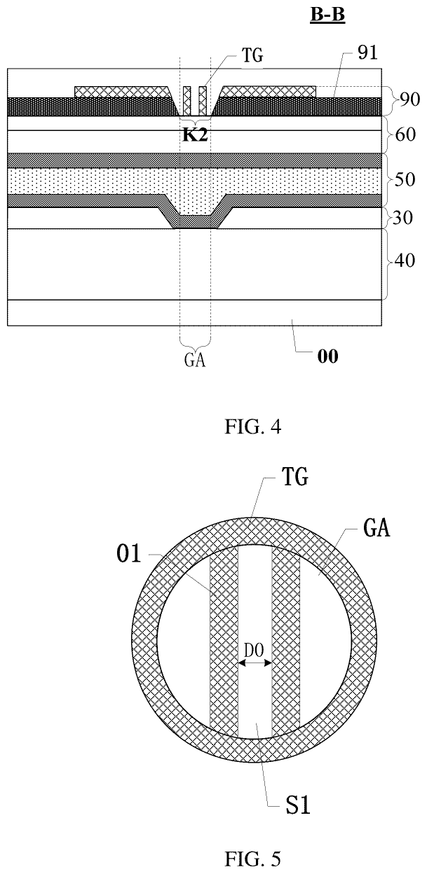

To solve the above technical problems, the embodiments of the present disclosure provide a display panel referring to FIG. 1 and FIG. 3 to FIG. 5. FIG. 3 is a schematic diagram of a layer in a display region AA of the display panel shown in FIG. 1. FIG. 4 is a cross-sectional view along the direction BB of the display panel shown in FIG. 1, corresponding to a layer structure of the photosensitive region GA. FIG. 5 is a planar schematic diagram of the display panel in the photosensitive region GA. The display panel includes an array layer 40, a light-emitting functional layer 30, a first functional layer 90 and a light-adjusting portion TG. The light-emitting functional layer 30 is located on one side of the array layer 40 and is electrically connected to the array layer 40. The first functional layer 90 is located on a side of the light-emitting functional layer 30 away from the array layer 40. The first functional layer 90 includes a light-shielding layer 91 and a light-filtering portion 92. The light-shielding layer 91 includes a plurality of display openings K1 and at least one photosensitive opening K2. The display openings K1 and the photosensitive opening K2 penetrate through the light-shielding layer 91 along the thickness direction of the display panel. The display openings K1 are located in the display region AA, the photosensitive opening K2 is located in the photosensitive region GA, and the light-filtering portion 92 is located in the display opening K1. The light-adjusting portion TG is located in the photosensitive opening K2. Along the thickness direction of the display panel, the thickness of the light-adjusting portion TG is less than or equal to the thickness of the light-filtering portion 92.

An exemplary description of the layer structure of the display panel will be given first below. Referring to FIG. 3, the present disclosure takes the display panel being an Organic Light-Emitting Diode (OLED) display panel as an example, and the array layer 40 is arranged on one side of the substrate 00. The light-emitting functional layer 30 includes a plurality of light-emitting elements D. A basic structure of the light-emitting element D includes a first electrode 31, a light-emitting layer 32, and a second electrode 33. The first electrode 31 is an anode, and the second electrode 33 is a cathode. In some embodiments, the light-emitting functional layer 30 includes a pixel definition layer 34, and the pixel definition layer 34 defines a plurality of pixel openings. The light-emitting layer 32 is at least located in the pixel openings. Along a direction perpendicular to the substrate 00, the first electrode 31 and the second electrode 33 are respectively located on two sides of the light-emitting layer 32, and the first electrode 31 is located on a side of the second electrode 33 facing the substrate 00. The first electrode 31 is electrically connected to the array layer 40. The array layer 40 is provided with a pixel driving circuit for providing a driving voltage to the light-emitting element D to drive the light-emitting element to emit light. The pixel driving circuit includes a plurality of transistors T. When an appropriate voltage is supplied, holes generated by the first electrode 31 and electrons generated by the second electrode 33 combine in the light-emitting layer 32 to generate bright light.

In some embodiments, in the array layer 40, a gate of the transistor T is arranged in a first metal layer m1, and a source and a drain of the transistor T are arranged in a second metal layer m2. In some embodiments, the array layer 40 further includes an active layer 03 arranged on a side of the first metal layer m1 facing the substrate 00 and an auxiliary metal layer m0 arranged on a side of the active layer 01 facing the substrate 00. Along a direction perpendicular to the plane of the substrate 00, the first metal layer m1 and the auxiliary metal layer m0 both overlap with the active layer 03. The auxiliary metal layer m0 has a light-shielding effect, so as to prevent light from affecting the active layer 03. In some embodiments, a capacitor metal layer mc is further provided between the first metal layer m1 and the second metal layer m2, and the capacitor metal layer mc may form a capacitor structure with the second metal layer m2 or the first metal layer m1. In some embodiments, a third metal layer m3 is further provided on a side of the second metal layer m2 away from the substrate 00, and another metal layer may be provided on a side of the third metal layer m3 away from the substrate according to actual needs, which is not limited in the present disclosure. Signal lines may be arranged on each metal layer. For example, power lines may be arranged on the third metal layer m3. The embodiments take the example in which the anode 31 of the light-emitting element D is electrically connected to the transistor T in the array layer 40 through the third metal layer m3 for description.

In some embodiments, an encapsulation layer 50 is further provided on a side of the second electrode 33 of the light-emitting element D away from the first electrode 31. In some embodiments, the encapsulation layer 50 includes an organic encapsulation layer 51 and two inorganic encapsulation layers 52 that are stacked, and the organic encapsulation layer 51 is located between the two inorganic encapsulation layers 52. In some embodiments, a touch layer 60 is provided on a side of the encapsulation layer 50 away from the substrate 00, and the touch layer 60 includes at least one touch metal layer, so as to realize the touch function of the display panel. The first functional layer 90 mentioned in the embodiments of the present disclosure may be arranged on a side of the touch layer 60 away from the substrate 00. The first functional layer 90 includes a light-shielding layer 91 and a light-filtering portion 92. The light-shielding layer 91 includes a plurality of display openings K1 and at least one photosensitive opening K2. Along the thickness direction of the display panel, the display openings K1 and the photosensitive opening K2 penetrate through the light-shielding layer 91. The display openings K1 are located in the display region AA, the photosensitive opening K2 is located in the photosensitive region GA, and the light-filtering portion 92 is located in the display opening K1. The light-filtering portion 92 may include, for example, a red light-filtering portion, a blue light-filtering portion, and a green light-filtering portion.

In some embodiments, the display openings K1 and the photosensitive opening K2 are a plurality of through holes located on the light-shielding layer 91. The display openings K1 are located in the display region AA, which defines the actual light-emitting region of the sub-pixels in the display panel, and allows the light emitted by the light-emitting element D below to pass through. The light-shielding layer 91 functions to separate different sub-pixels to prevent mixing of light of different colors, and absorb stray light to reduce reflection and scattering of ambient light inside the display panel, so as to improve the display contrast. The light-filtering portion 92 is located in the display opening K1. The purpose of introducing the light-filtering portion 92 is to filter out light of unnecessary wavelengths in the light emitted by the light-emitting functional layer, and only allow specific light to pass through, thereby imparting a required color to each sub-pixel. The light-filtering portion 92 can make the wavelength range of the transmitted light narrower and more concentrated, thereby improving the color saturation and purity of the display image.

Referring to FIG. 4 and FIG. 5, compared with the solution in which a photosensitive hole is hollowed out in the related art, the present disclosure introduces a light-adjusting portion TG into the photosensitive opening K2, which is equivalent to introducing a thin film structure into the photosensitive opening K2. Such a thin film structure adjusts the optical characteristics at the photosensitive opening K2 through an optical interference principle (similar to an anti-reflection film), and cancels part of reflection of incident light through an optical interference effect of the thin film structure, thereby greatly reducing the reflectivity of the photosensitive region GA to below 0.1%, and solving the problem that the photosensitive opening K2 is obviously visible in the display panel in the screen-off state. In addition, in some embodiments of the present disclosure, the thickness of the light-adjusting portion TG to the photosensitive opening K2 is less than or equal to the thickness of the light-filtering portion 92 in the display opening K1. In this way, the absorption of the light by the light-adjusting portion TG can be minimized, so as to minimize the attenuation of the light while ensuring the anti-reflection effect, thereby ensuring that the photosensitive device corresponding to the photosensitive region GA can receive sufficient light signals, and ensuring normal functions thereof. In some embodiments of the present disclosure, the thickness configuration manner of the light-adjusting portion TG and the light-filtering portion 92 enables the display panel according to the embodiments of the present disclosure achieves a balance between the two contradictory technical requirements of high transmittance (ensuring the function of the photosensitive device) and low reflection (appearance requirement), which is beneficial to improving the appearance of the product in the screen-off state, thereby effectively improving the user's experience effect.

Continuing to refer to FIG. 4 and FIG. 5, in some embodiments of the present disclosure, the light-adjusting portion TG occupies less than 100% of an area of the photosensitive opening K2. In this case, the photosensitive opening K2 is not completely covered by the light-adjusting portion TG, and the light-adjusting portion TG may be embodied as a patterned structure rather than a complete planar covering structure. Considering that, if any layer is introduced into the photosensitive opening K2, even a layer having high transmittance will cause a certain absorption and reflection loss to visible light. When a part of the area of the photosensitive opening K2 is kept uncovered, it is equivalent to reserving a fully light-transmitting region, which can maximize the luminous flux (total light intensity) entering the photosensitive device below, such as an ambient light sensor. Especially for a sensor that needs to receive multi-angle incident light, the patterned non-complete covering structure may have better light coupling efficiency than a uniform thin film, thereby ensuring the reliability of the photosensitive function of the photosensitive device.

In addition, if the photosensitive opening K2 is not completely covered by the light-adjusting portion TG, when the light-adjusting portion TG exists in the photosensitive opening K2 in a patterned form, the photosensitive opening K2 is actually composed of two parts of regions. One part is the region covered by the light-adjusting portion TG (having lower reflectivity), and the other part is the region not covered by the light-adjusting portion TG (being completely hollowed out and having higher reflectivity). By finely controlling the coverage area of the light-adjusting portion TG and the size of the pore, the optical effect generated by the patterned structure can be utilized to achieve more optimized reflectivity matching, thereby reducing the average reflectivity of the photosensitive region GA to a lower level, which is beneficial to improving the appearance of the product in the screen-off state.

Continuing to refer to FIG. 5, in some embodiments of the present disclosure, in the photosensitive opening K2, the light-adjusting portion TG includes at least two light-adjusting sub-portions 01. A first gap S1 is formed between adjacent light-adjusting sub-portions 01, and the width of the first gap S1 is greater than 0. In this way, it is equivalent to introducing the light-adjusting sub-portion 01 to perform the patterned design the light-adjusting portion TG. In practical applications, the effective refractive index and the effective film thickness of the photosensitive hole region can be adjusted by accurately designing the width and period of the light-adjusting sub-portion 01 and the first gap S1 (i.e., the exposed region). Such a patterned structure can generate diffraction and scattering effects, and better match with the film stack of the surrounding normal display region AA using the optical thin film interference principle, thereby realizing the optimal anti-reflection effect in the visible light band. In addition, the existence of the first gap S1 ensures that some regions are completely transparent, thereby maximizing the luminous flux. In addition, the patterned structure can scatter or guide the ambient light incident into the photosensitive hole, so that the ambient light more effectively enters the photoelectric sensing device with a smaller area below, thereby enhancing the photosensitive sensitivity.

In addition, considering that a continuous large-area thin film are prone to uneven stress or morphological defects during processing, dividing the light-adjusting portion TG into independent sub-structures can effectively release the thin film stress, improve the structural stability of the layer in the photosensitive hole region, and reduce the visual non-uniformity caused by structural defects.

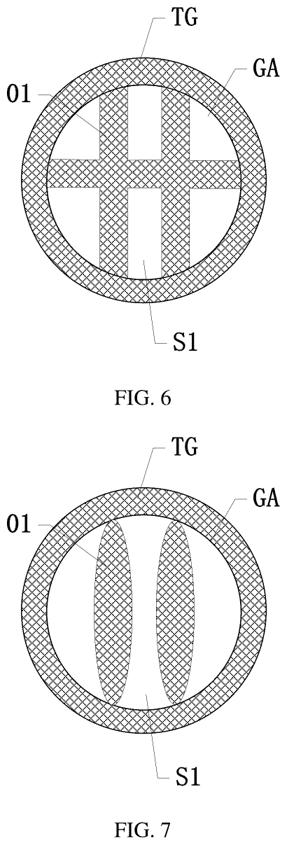

FIG. 6 to FIG. 8 respectively show a planar schematic diagram of the display panel in the photosensitive region GA. Referring to FIG. 5 to FIG. 8, in some embodiments of the present disclosure, the edge of the orthographic projection of the first gap S1 on the light-emitting surface of the display panel includes at least one of a line segment and an arc.

During the manufacturing process of the display panel, the microstructure is formed through technologies such as photolithography and etching. When the edge of the orthographic projection of the first gap S1 includes a line segment structure, for example, referring to FIG. 5 and FIG. 6, the pattern design and transfer of the photolithography mask are simpler and more accurate compared with other complex structures, which helps to ensure the dimensional accuracy and the positional accuracy of the light-adjusting sub-portion 01 and the first gap S1, and reduces the yield problem caused by pattern transfer errors. If the light-adjusting sub-portions 01 are arranged in periodic fine stripes (line segment structures), the entire photosensitive hole region forms a periodic grating structure. The periodic line segment structure is easy to establish an optical model, facilitating engineers to accurately predict and design the diffraction efficiency, transmittance and reflectivity. Such regularity can simplify optical regulation, making the calibration of reflectivity and transmittance and mass production easier to control. In addition, a specific line segment pattern (such as parallel fine stripes) may be used to scatter or diffract the incident light in a specific direction using the diffraction effect. If the sensor needs light to enter at a specific angle or direction (for example, a direction perpendicular to the display panel), the carefully designed line segment structure can serve as a micro light-guiding grating, thereby improving the efficiency of light coupling to the sensor.

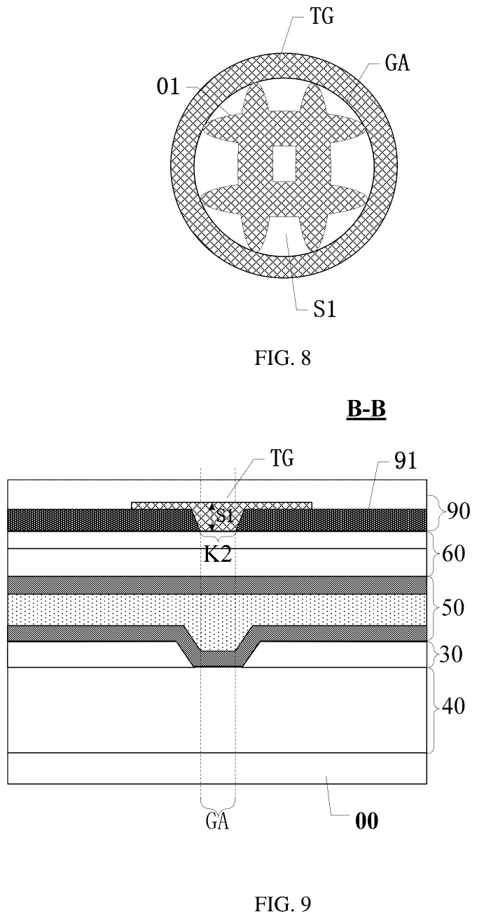

In addition, if the orthographic projection of the first gap S1 includes an arc, for example, referring to FIG. 7 and FIG. 8, an arc edge (i.e., a rounded corner or a curved surface transition) may be used to smooth the diffraction effect of light, reduce the directional scattering of light, and make the distribution of light in the photosensitive hole region more uniform, which helps to eliminate defects such as halos or rainbow patterns caused by diffraction, and is crucial for sensors that need to uniformly receive ambient light. During the micro photolithography and etching process of semiconductors and display panels, sharp internal angles are often difficult to process precisely, which is prone to cause uneven etching, stress concentration or residue accumulation. Adopting the arc edge can avoid sharp corners, thereby improving the fidelity of the photoetching pattern and the stability of the process. The shape of the edge of the first gap S1 determines the manner in which the light interacts with the edge of the light-adjusting portion thin film. By carefully designing the arc edge, the effect of the microlens array can be simulated on a microscopic scale, and the incident ambient light is slightly refracted or converged. Such an optimized design can help to couple and guide ambient light to the photosensitive region of the photosensitive sensor below more effectively, further enhancing the sensitivity of the sensor.

It is understandable that, in some embodiments of the present disclosure, the edge of the first gap S1 may also be embodied as a composite structure of line segments and arcs. For example, the line segments may be used in the periodic main body portion of the light-adjusting portion pattern (such as long sides of fine stripes) to ensure high precision and periodicity, thereby achieving the precise anti-reflection effect. Arcs may be used for smooth transition at corners or endpoints of the pattern, to eliminate the photoelectric defects and process risks caused by sharp corners, thereby maximally balancing the ultimate optimization of optical performance (smoothing diffraction through arcs) and the stability and controllability of large-scale mass production (ensuring precision through line segments).

It should be noted that the embodiments of the present disclosure do not limit the form of the patterned light-adjusting portion, which may be strip-shaped, grid-shaped, or any other feasible shape.

Referring to FIG. 5, in some embodiments of the present disclosure, the width of the first gap S1 is D0, and 3 μm≤D0≤8 μm. The width direction of the first gap S1 is perpendicular to the extending direction of the first gap S1 and parallel to the light-emitting surface of the display panel.

Considering that if the width D0 of the first gap S1 is too large (for example, greater than 8 μm), the area of the exposed region that does not cover the light-adjusting portion TG will increase significantly, leading to a sharp rise in the reflectivity of this region, which makes it difficult for the average reflectivity of the photosensitive hole region to reach the target of less than 0.1%, thereby affecting the appearance. If the gap width is too small (for example, less than 3 μm), the photolithography resolution and etching precision during manufacturing will face challenges, and defects such as open circuits, short circuits or non-uniform dimensions are prone to occur, thereby affecting the yield. Therefore, 3 μm≤D0≤8 μm is configured in some embodiment, which ensures that under the existing process conditions, a certain light-transmitting amount and patterned precision can be maintained, and the average reflectivity can also be effectively controlled, so as to avoid visually visible defects. In some embodiments, 4 μm≤D0≤7 μm, or 3.5 μm≤D0≤6.5 μm, which is not limited in the present disclosure.

When the light-adjusting portion TG occupies less than 100% of an area of the photosensitive opening K2, in some embodiments, the thickness of the light-adjusting portion TG is the same as the thickness of the light-filtering portion 92. In this case, the light-adjusting portion TG and the light-filtering portion 92 may be manufactured in the same layer. During the manufacturing of the first functional layer 90, the thickness difference does not need to be achieved using a complex Gray-tone Mask or Halftone Mask. It is only necessary to use a conventional photolithography mask to define the planar pattern of the light-adjusting portion TG (with the area percentage of less than 100%), which greatly simplifies the process steps and control difficulty, and is beneficial to large-scale mass production and yield improvement. In this case, the optical performance is completely determined by the duty cycle and period of the planar pattern. By precisely controlling the pattern size, the balance between reflectivity and transmittance can be achieved more accurately. The first gap S1 (the uncovered region) serves as a pure light-transmitting channel, which ensures that the maximum luminous flux entering the sensor and is beneficial to improving the sensitivity of the sensor.

When the light-adjusting portion TG occupies less than 100% of an area of the photosensitive opening K2 is less than 100%, the thickness of the light-adjusting portion TG may be flexibly configured according to the area ratio of the light-adjusting portion TG to the photosensitive opening K2. For example, when the area ratio of the light-adjusting portion TG to the photosensitive opening K2 is relatively large, the thickness of the light-adjusting portion TG may be configured to be relatively small, so as to improve light transmittance while achieving anti-reflection. On the contrary, when the area ratio of the light-adjusting portion TG to the photosensitive opening K2 is relatively small, the thickness of the light-adjusting portion TG may be configured to be relatively large, so as to improve the anti-reflection effect while ensuring the transmittance. That is, the area ratio of the light-adjusting portion TG to the photosensitive opening K2 is inversely correlated with the thickness of the light-adjusting portion TG, which can ensure the anti-reflection effect and help to ensure the light-transmitting amount of the photosensitive region.

The above embodiments describe the solution in which the light-adjusting portion TG occupies less than 100% of an area of the photosensitive opening K2, but the present disclosure is not limited thereto. In some embodiments of the present disclosure, the light-adjusting portion TG may occupy 100% of an area of the photosensitive opening K2. For example, referring to FIG. 9, FIG. 9 is a cross-sectional view along the direction BB of the display panel shown in FIG. 1. In some embodiments, the photosensitive opening K2 is fully covered by the light-adjusting portion TG, which can realize a relatively comprehensive and uniform anti-reflection effect, making the optical properties of a region of the photosensitive opening K2 more uniform. In addition, the non-patterned design manner is also beneficial to simplifying the manufacturing process.

In some embodiments, referring to FIG. 9 and FIG. 3, when the light-adjusting portion TG occupies 100% of an area of the photosensitive opening K2, along the thickness direction of the display panel, the maximum thickness S1 of the light-adjusting portion TG is less than the thickness S2 of the light-filtering portion 92. By thinning the thickness of the light-adjusting portion TG, the destructive interference can be generated between the light-adjusting portion TG and the reflected light at the interface of the upper layer and the lower layer, thereby minimizing the reflection of ambient light, and reducing the reflectivity of the photosensitive region GA to below 0.1%. Although the light-adjusting portion TG covers 100% of the area of the photosensitive opening K2, since the thickness of the light-adjusting portion TG is thinned, the absorption loss when light passes through is controlled to be very low. By optimizing the thinned thickness, an optimal balance point can also be found between anti-reflection and high transmittance.

In some embodiments of the present disclosure, when the photosensitive opening K2 is fully covered by the light-adjusting portion TG with a relatively small thickness, the thickness of the light-adjusting portion TG may be uniform. In this way, the diffraction and scattering effects caused by the patterning period are not generated, completely avoiding the defects such as halos or rainbow patterns caused by the periodicity of the surrounding patterns.

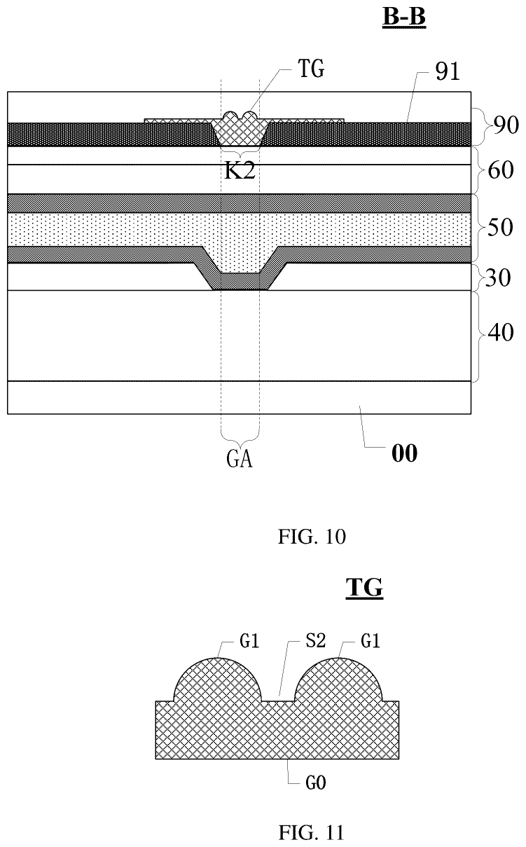

It is understandable that, in some embodiments of the present disclosure, when the photosensitive opening K2 is fully covered by the light-adjusting portion TG, the surface of the light-adjusting portion TG may also present a non-planar structure. For example, referring to FIG. 10 and FIG. 11, FIG. 10 is a cross-sectional view along the direction BB of the display panel shown in FIG. 1, and FIG. 11 is an enlarged schematic diagram of the light-adjusting portion TG shown in FIG. 10. In some embodiments of the present disclosure, the light-adjusting portion TG includes a main body portion G0 and at least two protruding portions G1 arranged on a side of the main body portion G0 away from the array layer. The main body portion G0 covers the photosensitive opening K2. A second gap S2 is provided between adjacent protruding portions G1, and the width of the second gap S2 is greater than 0.

In some embodiment, the main body portion G0 in the light-adjusting portion TG covers 100% of the area of the photosensitive opening K2. At least two protruding portions G1 are provided on a side of the main body portion G0 away from the array layer, forming a non-planar surface on a side of the light-adjusting portion TG, which can be used for scattering, diffracting or focusing light. In addition, the gap width between adjacent protruding portions G1 is greater than 0, ensuring that air or a low-refractive-index material is filled between the protruding portions G1, which can realize a grating or a lens effect. In the microscopic scale, when light enters the array formed by the protruding portions G1 from air, it can be regarded as passing through an interface with a gradually changing effective refractive index. Such a gradient refractive index structure can greatly eliminate Fresnel reflection and achieve ultra-low reflection with a wider wave band and a lower angle than a traditional thin film, which is beneficial to further reducing the refractive index of the photosensitive region GA to below 0.1%, even close to 0, thereby greatly improving the appearance of the product in the screen-off state, and improving the user's experience effect. In practical applications, the curved surface morphology or periodic arrangement of the protruding portions G1 may be designed as a microlens array or a grating. The protruding curved surface can refract and converge ambient light incident at large angles, and effectively guide the ambient light to the photosensitive region of the photosensitive device below, significantly improving the light coupling efficiency and sensitivity of the ambient light sensor, and enabling the sensor to work stably even when the light is weak or incident at large angles. In some embodiment, the microstructure formed by the protruding portions G1 achieves effective anti-reflection, and the light loss at the reflection portion is greatly reduced, thereby improving the corresponding transmittance. The problem of appearance reflection is solved, and the sufficient optical signals required for the sensing function of the photosensitive device are ensured.

Continuing to refer FIG. 10 and FIG. 11, in some embodiments of the present disclosure, the main body portion G0 and the protruding portion G1 are integrally formed. That is, the main body portion G0 and the protruding portion G1 are formed in one step at a time from the same material. If the main body portion G0 and the protruding portion G1 are manufactured separately, two independent steps are required: first depositing and patterning the main body portion G0, and then depositing and patterning the protruding portions G1. However, in the present disclosure, the main body portion G0 and the protruding portion G1 adopt an integrally formed structure. By using a single photolithography step and a single development/etching step, thickness differences and morphology differences can be generated in different regions of the material by precisely controlling the exposure dose of the photoresist (e.g., using a gray-tone mask), thereby forming the main body portion G0 and the protruding portion G1 at a time in the same layer. The method significantly reduces the number of masks, equipment occupation time and process alignment errors, and is the most economical and efficient manufacturing method for realizing the structure functions.

In addition, if the main body portion G0 and the protruding portion G1 are of a separate structure, an interface is formed between the main body portion G0 and the protruding portion G1. This interface may have problems such as stress mismatch, refractive index discontinuity, or chemical residues. However, in the present disclosure, the main body portion G0 and the protruding portion G1 are continuously formed by using the same material, which eliminates the interface, so that the main body portion G0 and the protruding portion G1 are completely continuous in structure and chemistry, thereby avoiding interface reflection and interface scattering, and improving the efficiency of light transmission and light collection. In addition, the mechanical strength and adhesion of the protruding structure are enhanced, and the risk of peeling or fracture in the subsequent processes or use is reduced. In addition, when the main body portion G0 and the protruding portion G1 are integrally formed by using the same material, it is ensured that the main body portion G0 and the protruding portion G1 are made of materials with exactly the same refractive index and extinction coefficient, which greatly simplifies the optical design, makes the regulation of the microlens/grating effect more predictable, and ensures that the optical responses of the photosensitive region at different wavelengths are more consistent.

Referring to FIG. 3, FIG. 9 and FIG. 10, in some embodiments of the present disclosure, the light-adjusting portion TG and at least part of the light-filtering portion 92 are arranged in the same layer. If the light-adjusting portion TG and the light-filtering portion 92 are in different layers, multiple depositions, multiple photolithography processes, and multiple etching processes are required. The light-adjusting portion TG being arranged in the same layer as at least part of the light-filtering portion 92 means that the light-adjusting portion TG and the light-filtering portion 92 (or at least part of the light-filtering portion TG) may be deposited and patterned in a single step at a time. For example, if the light-adjusting portion TG adopts a green color resist, and the light-filtering portion 92 also includes a green color resist, the light-adjusting portion TG and the light-filtering portion 92 may be formed in the same process step of depositing the green color resist, which greatly reduces the total process time and manufacturing cost, and is beneficial to realizing large-scale mass production.

In addition, in the multi-layer structure of the display panel, the alignment accuracy between layers is a key factor affecting the yield. The light-adjusting portion TG and the light-filtering portion 92 are located in the same layer, and the reference for aligning the light-adjusting portion TG and the light-filtering portion 92 is the layer itself, without considering the complex alignment relationship between the upper and lower layers, effectively eliminates the alignment error between the light-adjusting portion TG and the light-filtering portion 92, ensures that the light-adjusting portion TG can accurately cover or be patterned in the photosensitive opening K2, and greatly improves the manufacturing precision and yield. Since the light-adjusting portion TG is designed as a derivative structure of the light-filtering portion 92 (for example, a thinned or patterned region of the light-filtering portion 92), the light-adjusting portion TG and the light-filtering portion 92 may use materials having similar or identical chemical properties (e.g., both using color resist materials), avoiding chemical compatibility problems (such as stress mismatch and poor adhesion) that may be caused by the introduction of new materials, and making the overall film stack structure more stable.

In some embodiments of the present disclosure, the light-filtering portion 92 includes a red light-filtering portion, a green light-filtering portion and a blue light-filtering portion, and the light-adjusting portion TG and the green light-filtering portion are arranged in the same layer.

The spectral peaks of sunlight and most artificial light sources tend to concentrate in the middle band of visible light (i.e., near yellow and green light, e.g., about 550 nm). In addition, among the green light-filtering portion, the red light-filtering portion and the blue light-filtering portion, the green light-filtering portion is the material with the highest transmittance for visible light. The spectral transmission curve of the green light-filtering portion best matches the wavelength range to which the human eye is most sensitive (about 555 nm) and the spectral peak of ambient light. Therefore, when the light-adjusting portion TG and the green light-filtering portion are arranged in the same layer, which ensures that the photosensitive sensor can receive the strongest and most effective signal in the ambient light. This is critical for ensuring the fast and accurate response of the sensor in various environments, especially low-light environments. Such a design makes the response of the sensor to the ambient light closer to the perception of human eyes, which helps to achieve more natural and comfortable automatic brightness adjustment.

The light-adjusting portion TG being arranged in the same layer as the green color resist in the light-filtering portion 92 can directly utilize the equipment and process flows for deposition, photolithography, and etching of green color resist, so as to avoid adding a separate layer for the light-adjusting portion TG or adopting a new material, and to reduce the manufacturing complexity and cost. Whether forming a thinned layer (the thickness of the light-adjusting portion TG is less than the thickness of the light-filtering portion 92) or forming a patterned structure (the coverage area of the light-adjusting portion TG on the photosensitive opening K2 is less than 100%), the light-adjusting portion TG can be realized by combining a gray-tone mask or a conventional mask in a single photolithography step for the green color resist, thereby maximizing the use of existing process resources.

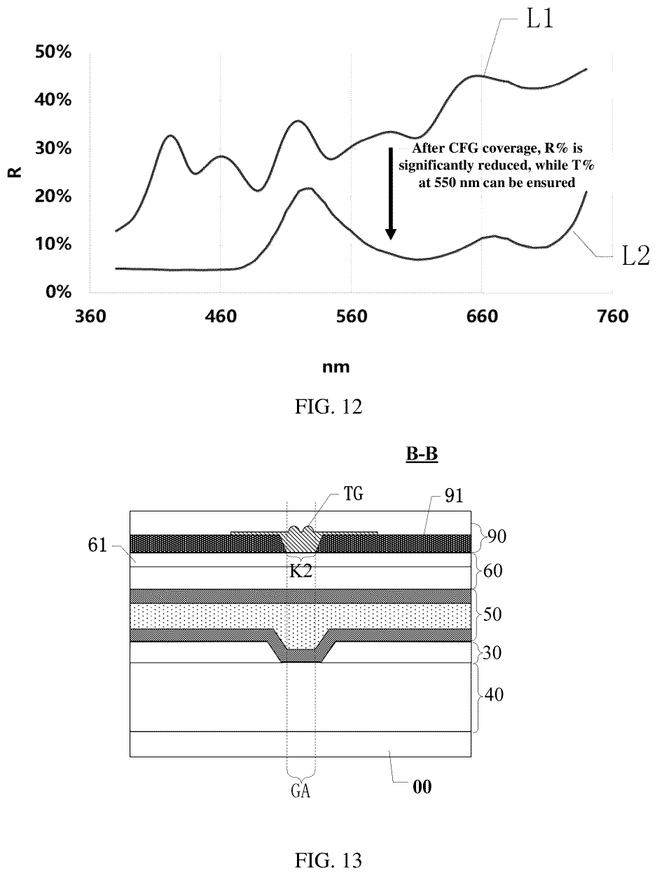

FIG. 12 is a schematic diagram of a reflection spectrum of a photosensitive region. In the two lines, Line L1 represents the reflection spectrum when no light-adjusting portion is introduced into the photosensitive region, Line L2 represents the reflection spectrum when the green color resist CFG in the light-filtering portion 92 is introduced as the light-adjusting portion in the photosensitive region. The abscissa represents the spectrum, and the ordinate represents the reflectivity. It can be seen that when no light-adjusting portion is introduced, the reflectivity of the photosensitive region is relatively high. After the light-adjusting portion is introduced into the photosensitive region, the reflectivity R % of the photosensitive region is effectively reduced, and the transmittance T % of the photosensitive region at 550 nm can be ensured.

In some embodiments of the present disclosure, the light-filtering portion 92 includes a red light-filtering portion, a green light-filtering portion and a blue light-filtering portion, and the light-adjusting portion TG and the red light-filtering portion or the blue light-filtering portion are arranged in the same layer.

If in the panel design, the manufacturing steps of the red color resist or the blue color resist in the light-filtering portion are more convenient to integrate additional patterning (thinning or non-100% coverage) for some reason, the light-adjusting portion TG is arranged in the same layer as the color resist corresponding to the red light-filtering portion or the blue light-filtering portion, so as to avoid adding additional photolithography steps. Maintaining the same-layer arrangement eliminates the alignment error between the light-adjusting portion TG and the light-filtering portion 92, ensuring the manufacturing accuracy and yield. When the red light-filtering portion or the blue light-filtering portion is arranged in the same layer as the light-adjusting portion TG, the corresponding photosensitive device may be, for example, a device sensitive to red light or blue light, thereby meeting the sensing requirement of the display product for ambient light.

The above embodiments describe the solution where the light-adjusting portion TG is arranged in the same layer as the light-filtering portion 92. In some embodiments of the present disclosure, the light-adjusting portion TG and the light-filtering portion 92 may also be made of different materials. For example, referring to FIG. 13, FIG. 13 is a cross-sectional view along the direction BB of the display panel shown in FIG. 1. In some embodiments, different fillings are used for the light-adjusting portion TG and the light-filtering portion 92 to indicate that the two are made of different materials. When the light-adjusting portion TG is made of a material different from that of the light-filtering portion 92, the designer can customize the material completely according to the requirements of anti-reflection and high transmittance. For example, in some embodiments of the present disclosure, the transmittance spectrum peak position of the light-adjusting portion TG is different from the transmittance spectrum peak position of the light-filtering portion 92. The transmittance spectrum peak position of the light-adjusting portion TG is 550 nm, and the extinction coefficient at the wavelength of 550 nm satisfies 0.005≤k≤0.04.

The transmittance spectrum peak position of the color resist material adopted by the conventional light-filtering portion is about 530 nm, which corresponds to the peak position of the emission spectrum of the light-emitting element. When the light-adjusting portion in some embodiments is made of a material different from that of the light-filtering portion, a material with a transmittance spectrum peak position of 550 nm can be adopted. 550 nm is the most sensitive wavelength of human eyes, and is also one of the wavelengths where energy is concentrated in the ambient light spectrum. Setting the transmittance peak position of the light-adjusting portion TG at 550 nm ensures that the ambient light signal can pass through with the highest efficiency to the greatest extent, thereby ensuring the sensitivity of the ambient light sensor. The extinction coefficient k is a physical parameter that describes the degree of light absorption when light propagates in a material. The larger the k value is, the more light is absorbed, and the lower the transmittance is. In some embodiment, when the extinction coefficient k of the light-adjusting portion TG is set to be less than or equal to 0.04, the light-adjusting portion TG has extremely low light absorption, ensuring that light near 550 nm can pass through the light-adjusting portion TG with minimum loss, thereby meeting the requirement of the sensor on luminous flux. If the k value is too low (e.g., less than 0.005 or close to 0), the material hardly absorbs light. Although the transmittance is extremely high, it may be unfavorable for fine regulation of the reflectivity through slight absorption in cooperation with the interference effect. Therefore, the limitation of k≥0.005 ensures that the material has certain optical activity (i.e., the combined effect of the refractive index n and the extinction coefficient k), and can participate in the optical interference anti-reflection process to achieve precise regulation of reflectivity. In some embodiments, 0.005≤k≤0.04 is set, and the k value is limited to an extremely narrow and low range, so as to ensure that the light-adjusting portion TG can provide the optimal visible light transmittance while having the optical regulation capability. Such a customized light-adjusting portion TG design can achieve performance exceeding that of the conventional color resist materials constituting the light-filtering portion, and reach the ultimate balance between extremely low reflectivity and high transmittance.

Continuing to refer to FIG. 3, when the light-adjusting portion TG is made of a material different from that of the light-filtering portion, in some embodiments of the present disclosure, the transmittance per unit thickness of the light-adjusting portion TG at the peak position of 550 nm is greater than or equal to 80%. In this case, the light-adjusting portion TG absorbs very little light with a wavelength of 550 nm, so as to ensure that when light passes through the light-adjusting portion TG, only very little energy is absorbed by the material and converted into heat energy or loss. In this way, the luminous flux (total light intensity) enters the photosensitive device below, such as an ambient light sensor, can be ensured to the greatest extent, which is beneficial to improving the photosensitive reliability of the photosensitive device.

In some embodiments of the present disclosure, the refractive index of the light-adjusting portion TG is n, and 1.53≤n≤1.65. As an anti-reflection film, the light-adjusting portion TG utilizes the reflected light at the upper and lower interfaces of the thin layer to generate destructive interference, thereby cancelling the reflection. To achieve the optimal anti-reflection effect, the refractive index of the thin layer needs to satisfy specific conditions. In the OLED panel, the light-adjusting portion TG is generally located between the air interface (n_{air}≈1.0) and the organic or inorganic layer below (e.g., n_{lower layer}≈1.7~1.9). Due to the complex structure of the actual OLED film stack, a refractive index between 1.5 and 1.7 is generally required for matching, so as to minimize the reflection of the interface.

In some embodiments of the present disclosure, the refractive index of the light-adjusting portion TG is set to satisfy 1.53≤n≤1.65, which is exactly within the refractive index range of the conventional organic material, and is an ideal range for anti-reflection after optical engineering optimization. It can ensure that the light-adjusting portion TG forms an effective refractive index transition with the film stacks of the upper and lower layers of the panel, thereby reducing the reflectivity to the greatest extent and meeting the requirement of reducing the reflectivity to less than 0.1%.

In addition, the refractive index of most organic materials used for display panels (such as photoresist, color resist, planarization material, etc.) is around 1.5 to 1.7. When the light-adjusting portion TG with a refractive index satisfying 1.53≤n≤1.65 is adopted in the present disclosure, such a material with the refractive index is easy to synthesize, relatively low in cost, and have good thermal stability and chemical compatibility. The color resist or organic resin material similar to that of the light-filtering portion 92 may be used for manufacturing, which ensures good compatibility with the existing OLED manufacturing process.

In some embodiments, 1.55≤n≤1.6, or 1.58≤n≤1.64, which is not limited in the present disclosure.

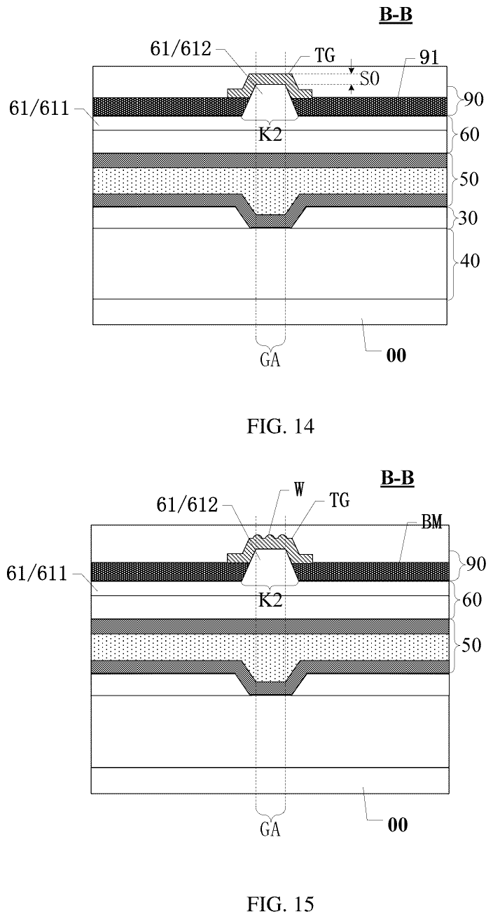

FIG. 14 is a cross-sectional view along the direction BB of the display panel shown in FIG. 1. In some embodiments of the present disclosure, along the thickness direction of the display panel, a first insulating layer 61 is provided between the first functional layer 90 and the light-emitting functional layer, and the first insulating layer 61 is arranged adjacent to the first functional layer 90. When a touch layer 60 is provided between the first functional layer 90 and the encapsulation layer 50 in the display panel, the first insulating layer 61 may be regarded as a touch insulating layer in the touch layer 60. It should be noted that when the touch layer 60 is not provided in the display panel, the first functional layer 90 is in direct contact with the encapsulation layer 50, and the first insulating layer 61 may be embodied as an inorganic encapsulation layer arranged closest to the first functional layer 90 in the encapsulation layer 50. Referring to FIG. 13, the surface of the first insulating layer 61 facing the first functional layer 90 is planar. Or, referring to FIG. 14, the first insulating layer 61 includes a flat portion 611 and a raised portion 612, and along the thickness direction of the display panel, the flat portion 611 is located in the display region AA, the raised portion 612 is located in the photosensitive opening K2, and the surface of the raised portion 612 away from the array layer 40 is higher than the surface of the light-shielding layer 91 away from the array layer 40.

Referring to FIG. 13, when the surface of the first insulating layer 61 is plane, the first insulating layer 61 is in a flat form in both the display region AA and the photosensitive region GA, and the light-adjusting portion TG is directly located above the flat photosensitive opening K2 and covers the photosensitive opening K2 in a thinned or patterned form. This solution requires the light-adjusting portion TG to achieve anti-reflection through thickness control (thinning) or area patterning. The anti-reflection effect completely depends on the interference matching between the refractive index and film thickness of the material of the light-adjusting portion TG and the upper and lower interfaces. The manufacturing process corresponding to this structure is relatively mature, the process is simple, and the production cost is relatively low.

Referring to FIG. 14, when the first insulating layer 61 includes the flat portion 611 and the raised portion 612, the flat portion 611 is located in the display region AA, and the raised portion 612 is located in the photosensitive opening K2. In the photosensitive opening K2, the first insulating layer 61 forms a protruding microstructure (the raised portion 612). The surface of the raised portion 612 away from the array layer 40 is higher than the surface of the light-shielding layer 91 away from the array layer, and the light-adjusting portion TG is located above the surface of the raised portion 612. In some embodiments, the raised structure of the raised portion 612 may serve as a microlens, which can refract and converge the ambient light incident at a large angle, thereby improving the efficiency of light entering the sensor (light collection effect). The raised structure and the surrounding air or filler form an effective gradient refractive index, which can achieve ultra-low reflection with a wide angle and a wide spectrum, and is more conducive to improving the user's experience effect.

In addition, when the first insulating layer 61 includes the flat portion 611 and the raised portion 612, the material of the light-adjusting portion TG above (such as CFG color resist) is deposited on the TPOC raised portion 612 below. Due to the curved surface morphology and the height step of the raised portion 612, the thickness of the material subsequently deposited the light-adjusting portion TG on the top of the raised portion 612 naturally becomes thinner. Such naturally formed thickness difference (thin on the top of the raised portion 612 and thick at the flat portion of the display region AA) itself meets the thinning requirement of the light-adjusting portion TG without an additional ashing process, avoiding complex gray-tone photolithography, and greatly reducing the chances of alignment and patterning errors. Adopting more reliable morphology reflow to achieve thickness control has a larger process window and better stability than relying on precise exposure dose and etching time control (ashing), which greatly simplifies the manufacturing process, reduces production costs, and is conducive to large-scale mass production.

Continuing to refer to FIG. 14, in some embodiments of the present disclosure, when the first insulating layer 61 includes the flat portion 611 and the raised portion 612, the light-adjusting portion TG is located on a side of the raised portion 612 away from the array layer 40, and the thickness of the light-adjusting portion TG is S0, where 0.5 μm≤S0≤1.5 μm.

During the manufacturing process of the display product, it is extremely difficult to stably control the film thickness below 0.5 μm, especially when utilizing the natural thinning of the TPOC protrusion, which is prone to local damage, holes, or non-uniform thickness. As an organic film, the light-adjusting portion TG has insufficient structural strength and toughness when it is too thin (for example, less than 0.5 μm), and the structural defects such as cracking or peeling are prone to occur in subsequent deposition, thermal treatment, or panel use, affecting the product lifetime. When the light-adjusting portion TG is too thick (for example, greater than 1.5 μm), the energy absorbed by light when passing through increases significantly, and the ambient light signal is severely attenuated, which directly affects the response speed and accuracy of the ambient light sensor under low light. A thicker layer tends to cause reflected light to produce complicated multi-order interference, which may cause the reflected light to exhibit obvious color changes or rainbow patterns under different viewing angles or different illumination, i.e., interference fringes, seriously affecting uniformity of an appearance in a screen-off state. In addition, the increase in thickness means that more expensive organic materials (such as color resist) need to be consumed, which directly increases the material cost. In addition, the patterning and curing time of the thick film will also be correspondingly increased, reducing the production efficiency.

Therefore, in the embodiments of the present disclosure, 0.5 μm≤S0≤1.5 μm is set. Within the thickness range, the light-adjusting portion TG can simultaneously achieve efficient optical anti-reflection (satisfying that the reflectivity is less than 0.1%) and minimal light absorption (satisfying that the high sensitivity of the sensor), achieving a perfect balance between appearance and functionality, avoiding structural defects and process uncontrollability caused by ultra-thin layers, and ensuring the mechanical reliability and high yield of the structure. This range matches the natural thinning effect introduced by the raised portion 612 in the first insulating layer 61, thereby achieving the advantage of manufacturing simplification without an ashing process.

In some embodiments, 0.8 μm≤S0≤1.4 μm, or 1 μm≤S0≤1.3 μm, etc., which is not limited in the present disclosure.

Continuing to refer to FIG. 14, in some embodiments of the present disclosure, when the first insulating layer 61 includes the flat portion 611 and the raised portion 612, the light-adjusting portion TG occupies 100% of an area of the photosensitive opening K2, so that the light-adjusting portion TG forms a continuous thin film without gap, completely eliminating diffraction and scattering caused by a patterned period and edge effects, as well as resulting defects such as halos and rainbow patterns, which ensures that the photosensitive hole region has extremely high visual uniformity in the screen-off state.

In some embodiment, the light-adjusting portion TG covers the raised portion 612 in the photosensitive opening K2, so that the light-adjusting portion TG also presents a protruding morphology. Such a double-protrusion structure (or continuation of topography) allows the photosensitive region to form a thicker and more efficient composite microlens structure, further enhancing the refraction and convergence of ambient light, allowing light to be more accurately and efficiently coupled into the photosensitive sensor below, and maximizing the sensitivity of the sensor. An organic structure with a protruding morphology usually has higher mechanical strength and scratch resistance than a flat thin film, improving the structural stability of the photosensitive region, and being beneficial to protecting the functional layer below.

FIG. 15 is a cross-sectional view along the direction BB of the display panel shown in FIG. 1. Referring to FIG. 15, in some embodiments, the surface of the light-adjusting portion TG away from the raised portion 612 includes a plurality of protruding microstructures W, for example, a conical or hemispherical structure. These protruding microstructures W may be arranged on the surface of the light-adjusting portion TG in an array. In this way, a moth-eye-like structure may be formed on the surface of the light-adjusting portion TG. Such a structure can realize ultra-low reflection in an extremely wide range of angles and wavelengths, and its performance far exceeds that of traditional thin film interference anti-reflection, further improving the user's experience effect.

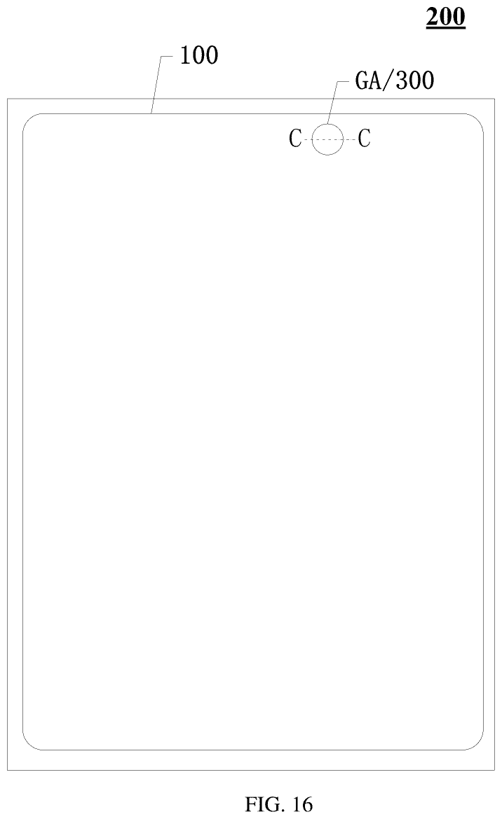

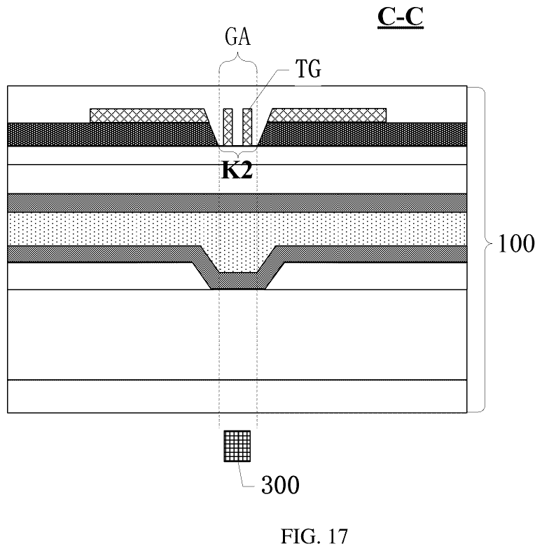

Based on the same inventive concept, the present disclosure further provides a display device. FIG. 16 is a planar schematic diagram of a display device according to some embodiments of the present disclosure, and FIG. 17 is a cross-sectional view along the direction CC of the display device shown in FIG. 16, showing the layer structure of the photosensitive region GA. Referring to FIG. 16 and FIG. 17, the display device 200 according to some embodiments of the present disclosure includes a photosensitive device 300 and the display panel 100 according to any one of the above embodiments. Along the thickness direction of the display device 200, the photosensitive device 300 overlaps with the photosensitive opening K2. It should be noted that, the embodiments of FIG. 17 only shows one morphology of the light-adjusting portion TG in the photosensitive region GA, but does not limit the specific morphology of the light-adjusting portion TG. The light-adjusting portion TG in the display device may adopt the structure of the light-adjusting portion according to any one of the above embodiments.

The display device 200 according to the embodiments of the present disclosure may be any electronic device having a display function, such as a touch display screen, a mobile phone, a tablet computer, a notebook computer, an e-book or a television. The display device 200 according to the embodiments of the present disclosure has the beneficial effects of the display panel according to the embodiments of the present disclosure. Reference may be made to the specific description of the display panel in the above embodiments, which will not be repeated herein.

It may be understood that FIG. 16 only illustrates a shape of the display device 200 by taking a rectangular structure as an example. In some embodiments of the present disclosure, the display device 200 may also be embodied as a circle, an ellipse or any other feasible shape, which is not limited in the present disclosure.

It should be noted that, in this context, relational terms such as “first” and “second” are merely used to distinguish one entity or operation from another entity or operation, and do not necessarily require or imply any actual relationship or sequence between these entities or operations. Further, terms such as “include”, “comprise” or any other variations thereof are intended to cover a non-exclusive inclusion, thus a process, method, item or device including a series of elements includes not only those elements, but also other elements not explicitly listed, or elements inherent in such the process, method, item or device. Without more limitations, an element defined by the statement “including a . . . ” does not exclude the existence of other identical elements in a process, a method, an article, or a device that include the element.

The above description is only some embodiments of the present disclosure, so that those skilled in the art can understand or implement the present disclosure. Various modifications to these embodiments will be apparent to those skilled in the art, and the general principles defined herein may be implemented in other embodiments without departing from the spirit or scope of the present disclosure. Accordingly, the present disclosure will not be limited to the embodiments described herein but should be interpreted to have the broadest scope in conformity with the principles and innovations disclosed in the present disclosure.

What is claimed is:

1. A display panel, comprising a photosensitive region and a display region at least partially surrounding the photosensitive region, the display panel comprising:
an array layer;
a light-emitting functional layer located on a side of the array layer and electrically connected to the array layer;
a first functional layer located on a side of the light-emitting functional layer away from the array layer, wherein the first functional layer comprises a light-shielding layer and a light-filtering portion, the light-shielding layer comprises a plurality of display openings and at least one photosensitive opening; and along a thickness direction of the display panel, the plurality of display openings and the at least one photosensitive opening penetrate through the light-shielding layer;
and the display openings are located in the display region, the photosensitive opening is located in the photosensitive region, and the light-filtering portion is located in one of the display openings; and
a light-adjusting portion located in the photosensitive opening, wherein along the thickness direction of the display panel, a thickness of the light-adjusting portion is less than or equal to a thickness of the light-filtering portion.

2. The display panel according to claim 1, wherein the light-adjusting portion occupies less than 100% of an area of the photosensitive opening.

3. The display panel according to claim 2, wherein in the photosensitive opening, the light-adjusting portion comprises at least two light-adjusting sub-portions, a first gap is formed between two adjacent light-adjusting sub-portions of the at least two light-adjusting sub-portions, and a width of the first gap is greater than 0.

4. The display panel according to claim 3, wherein an edge of an orthographic projection of the first gap on a light-emitting surface of the display panel comprises at least one of a line segment and an arc.

5. The display panel according to claim 3, wherein the width of the first gap is D0, 3 μm≤D0≤8 μm, and a width direction of the first gap is perpendicular to an extending direction of the first gap and parallel to a light-emitting surface of the display panel.

6. The display panel according to claim 1, wherein the light-adjusting portion occupies 100% of an area of the photosensitive opening.

7. The display panel according to claim 6, wherein along the thickness direction of the display panel, a maximum thickness of the light-adjusting portion is less than the thickness of the light-filtering portion.

8. The display panel according to claim 6, wherein the light-adjusting portion comprises a main body portion and at least two protruding portions arranged on a side of the main body portion away from the array layer, the main body portion covers the photosensitive opening, a second gap is formed between two adjacent protruding portions of the at least two protruding portions, and a width of the second gap is greater than 0.

9. The display panel according to claim 8, wherein the main body portion and the at least two protruding portions are integrally formed.

10. The display panel according to claim 1, wherein the light-adjusting portion is arranged in a same layer as at least part of the light-filtering portion.

11. The display panel according to claim 10, wherein the light-filtering portion comprises a red light-filtering portion, a green light-filtering portion and a blue light-filtering portion, and the light-adjusting portion is arranged in a same layer as the green light-filtering portion.

12. The display panel according to claim 10, wherein the light-filtering portion comprises a red light-filtering portion, a green light-filtering portion and a blue light-filtering portion, and the light-adjusting portion is arranged in a same layer as the red light-filtering portion or the blue light-filtering portion.

13. The display panel according to claim 1, wherein a transmittance spectrum peak position of the light-adjusting portion is different from a transmittance spectrum peak position of the light-filtering portion, the transmittance spectrum peak position of the light-adjusting portion is 550 nm, and an extinction coefficient k at a wavelength of 550 nm satisfies 0.005≤k≤0.04.

14. The display panel according to claim 13, wherein a transmittance per unit thickness of the light-adjusting portion at a peak position of 550 nm is greater than or equal to 80%.

15. The display panel according to claim 13, wherein a refractive index of the light-adjusting portion is n, and 1.53≤n≤1.65.

16. The display panel according to claim 1, wherein along the thickness direction of the display panel, a first insulating layer is provided between the first functional layer and the light-emitting functional layer, and the first insulating layer is arranged adjacent to the first functional layer;
a surface of the first insulating layer facing the first functional layer is planar; or
the first insulating layer comprises a flat portion and a raised portion, and along the thickness direction of the display panel, the flat portion is located in the display region, the raised portion is located in the photosensitive opening, and a surface of the raised portion away from the array layer is higher than a surface of the light-shielding layer away from the array layer.

17. The display panel according to claim 16, wherein when the first insulating layer comprises the flat portion and the raised portion, the light-adjusting portion is located on a side of the raised portion away from the array layer, a thickness of the light-adjusting portion is S0, where 0.5 μm ≤S0≤1.5 μm.

18. The display panel according to claim 17, wherein an area ratio of the light-adjusting portion to the photosensitive opening is 100%.

19. A display device, comprising a photosensitive device and a display panel, wherein
the display panel comprises a photosensitive region and a display region at least partially surrounding the photosensitive region, the display panel comprises:
an array layer;
a light-emitting functional layer located on a side of the array layer and electrically connected to the array layer;
a first functional layer located on a side of the light-emitting functional layer away from the array layer, wherein the first functional layer comprises a light-shielding layer and a light-filtering portion, the light-shielding layer comprises a plurality of display openings and at least one photosensitive opening; and along a thickness direction of the display panel, the plurality of display openings and the at least one photosensitive opening penetrate through the light-shielding layer; and the display openings are located in the display region, the photosensitive opening is located in the photosensitive region, and the light-filtering portion is located in one of the display openings; and
a light-adjusting portion located in the photosensitive opening, wherein along the thickness direction of the display panel, a thickness of the light-adjusting portion is less than or equal to a thickness of the light-filtering portion;
along a thickness direction of the display device, the photosensitive device overlaps with the photosensitive opening.
